(19) United States
(12) Patent Application Publication
(10) Pub. No.: US 2009/0237135 A1
(43) Pub. Date: Sep. 24, 2009

(54) SCHMITT TRIGGER HAVING VARIABLE HYSTERESIS AND METHOD THEREFOR

(76) Inventors: Ravindraraj Ramaraju, Round Rock, TX (US); Kenneth R. Burch, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/053,005

(22) Filed: Mar. 21, 2008

(51) Int. Cl. H03K 3/00

(52) U.S. Cl. 327/205

(57) ABSTRACT

A Schmitt trigger has a first inverter, a second inverter, a bias means, and a transistor. The inverter has an input and an output. The second inverter has an input coupled to the output of the first inverter and has an output. The bias means provides a first bias voltage on a first output terminal. A magnitude of the bias voltage is selectable by a first input signal. The transistor has a first current electrode coupled to a first power supply terminal, a control electrode coupled to the output of the second inverter, a second current electrode coupled to the output of the first inverter, and a body coupled to the first output terminal. Selectability of the magnitude of the bias voltage provides selectability of the hysteresis of the Schmitt trigger.

### BACKGROUND

1. Field

This disclosure relates generally to Schmitt triggers, and more specifically, to a Schmitt trigger having variable hysteresis and method therefor.

2. Related Art

Schmitt triggers are used in a variety of integrated circuit applications requiring hysteresis. For example, in one application, a Schmitt trigger is used to convert a sinusoidal input signal, such as a clock, to a pulse train. A Schmitt trigger has a hysteresis window comprising a low threshold voltage and a high threshold voltage. The high threshold voltage determines a transition point for a low-to-high signal transition, and the low threshold voltage determines a transition point for a high-to-low signal transition. In some applications, it is important that the low and high threshold voltages be precisely controlled. However, various factors such as manufacturing process variations and temperature changes may affect the low and high threshold voltages and adversely change the hysteresis window.

Therefore, what is needed is a Schmitt trigger that solves the above problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in schematic diagram form, a Schmitt trigger in accordance with an embodiment.

FIG. 2 illustrates the variable hysteresis window of the Schmitt trigger of FIG. 1.

### DETAILED DESCRIPTION

Generally, there is provided, a Schmitt trigger having a variable hysteresis window. The hysteresis window is adjusted by changing a threshold voltage of the hysteresis producing transistors of the Schmitt trigger. The threshold voltage is changed by selectively adjusting a body bias voltage of the hysteresis producing transistors. Adjusting the hysteresis window allows the hysteresis window to be controlled in response to factors such as manufacturing processing variations and temperature changes.

In one aspect, there is provided, a Schmitt trigger comprising: a first inverter having an input and an output; a second inverter having an input coupled to the output of the first inverter and an output; bias means for providing a first bias voltage on a first output terminal, wherein a magnitude of the bias voltage is selectable by a first input signal; and a first transistor having a first current electrode coupled to a first power supply terminal, a control electrode coupled to the output of the second inverter, a second current electrode coupled to the output of the first inverter, and a body coupled to the first output terminal. The first transistor may have a first conductivity type. The bias means may be further characterized as providing a second bias voltage on a second output terminal. A magnitude of the second bias voltage may be selectable by a second input signal. The Schmitt trigger may further comprise a second transistor having a first current electrode coupled to a second power supply terminal, a control electrode coupled to the output of the second inverter, a second current electrode coupled to the output of the first inverter, and a body coupled to the second output terminal. The first conductivity type may be P type. The second conductivity type may be N type. The first power supply terminal may be a VDD terminal. The second power supply terminal may be a ground terminal. The first inverter may comprise a second transistor having a first current electrode coupled to the output of the first inverter, a control electrode coupled to the input of the first inverter, and a second current electrode. The Schmitt trigger may also include a third transistor having a first current electrode coupled to the second current electrode of the second transistor, a second current electrode coupled to the first power supply terminal, and a control electrode coupled to the output of the first inverter. The second current electrode of the first transistor may be coupled to the output of the first inverter through the second transistor. The third transistor may have a body coupled to the first output terminal. The first inverter may comprise a fourth transistor having a first current electrode coupled to the output of the first inverter, a control electrode coupled to the input of the first inverter, and a second current electrode. The Schmitt trigger may further include a fifth transistor having a first current electrode coupled to the second current electrode of the fourth transistor, a second current electrode coupled to a second power supply terminal, and a control electrode coupled to the output of the first inverter. The bias means may be further characterized by being for providing a second bias voltage on a second output terminal. A magnitude of the bias voltage may be selectable by a second input signal. The Schmitt trigger may further include a sixth transistor having a first current electrode coupled to a second power supply terminal, a control electrode coupled to the output of the second inverter through the fourth transistor, a second current electrode coupled to the output of the first inverter, and a body coupled to the second output terminal. The first, second, and third transistors may be P type, and the fourth, fifth, and sixth transistors may be N type. The first input signal may further comprise a plurality of bits. The hysteresis of the Schmitt trigger may increase with an increase in magnitude of the first bias voltage.

In another aspect, in a Schmitt trigger, a method comprises: providing a first inverter having an input for receiving an input signal and having an output; providing a first transistor between a first power supply terminal and the output of the first inverter; selecting a threshold voltage for the first transistor; applying the input signal at a first logic state to the input of the first inverter, wherein the first transistor becomes conductive at a first voltage; transitioning the input signal from the first logic state to a second logic state, wherein the first transistor becomes non-conductive at a second voltage different from the first voltage. The step of selecting may be further characterized by a first select signal selecting the threshold voltage of the first transistor. The method may further comprise: changing the threshold voltage of the first transistor; and transitioning the input signal from the first logic state to a second logic state, wherein the first transistor becomes non-conductive at a third voltage different from the first voltage and the second voltage. The method may further comprise: providing a second transistor between a second power supply terminal and the output of the first inverter; and selecting a threshold voltage for the second transistor; wherein the step of applying the input signal at a first logic state to the input of the first inverter causes the second transistor to become non-conductive. The method may further comprise: changing the threshold voltage of the second transistor; and transitioning the input signal from the second logic state to the first logic state to cause the first transistor to become conductive at a third voltage different from the first voltage and the second voltage. The method may further comprise changing hysteresis of the Schmitt trigger by changing the threshold voltage of the first transistor.

In yet another aspect, a Schmitt trigger comprises: a first inverter having an input for receiving an input signal and having an output; first current means for supplying a first current to the output during a first portion of a transition of the input signal from a first logic state to a second logic state; and select means for altering a magnitude of the first current that is supplied to the first output during the first portion of the transition of the input signal from the first logic state to the second logic state. The first current means may comprise a first transistor having a threshold voltage that is selectable by the select means. The first current means may comprise: bias means for providing a first bias voltage on a first output terminal, wherein a magnitude of the bias voltage is selectable by a first input signal; and a first transistor having a first current electrode coupled to a first power supply terminal, a control electrode coupled to the output of the second inverter, a second current electrode coupled to the output of the first inverter, and a body coupled to the first output terminal. The bias means may provide a bias voltage to a body of the first transistor, and a magnitude of the bias voltage may be selectable by a multiple bit select signal.

The semiconductor substrate described herein can be any semiconductor material or combinations of materials, such as gallium arsenide, silicon germanium, silicon-on-insulator (SOI), silicon, monocrystalline silicon, the like, and combinations of the above.

Each signal described herein may be designed as positive or negative logic, where negative logic can be indicated by a bar over the signal name or an asterix (*) following the name. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

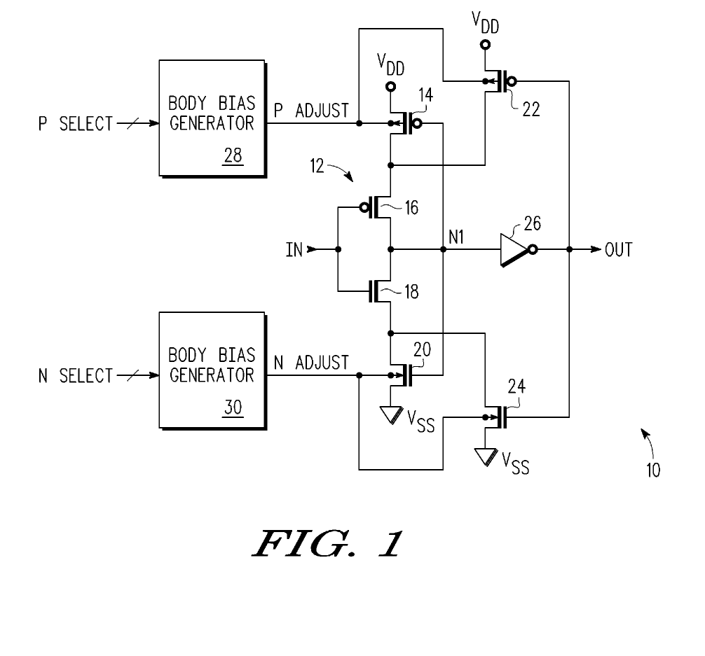

FIG. 1 illustrates, in schematic diagram form, Schmitt trigger 10 in accordance with an embodiment. Schmitt trigger 10 includes inverters 12 and 26, P-channel transistors 14 and 22, N-channel transistors 20 and 24, and body bias generators 28 and 30. Inverter 12 includes P-channel transistor 16 and N-channel transistor 18. P-channel transistor 14 has a source (current electrode) coupled to a power supply voltage terminal labeled “VDD”, a gate (control electrode) coupled to an internal node labeled “N1”, a drain (current electrode), and a body terminal coupled to receive a body bias voltage labeled “P ADJUST”. P-channel transistor 16 has a source coupled to the drain of P-channel transistor 14, a gate for receiving an input signal labeled “IN”, and a drain coupled to internal node N1. N-channel transistor 18 has a drain coupled to internal node N1, a gate coupled to receive input signal IN, and a source. N-channel transistor 20 has a drain coupled to the source of N-channel transistor 18, a gate coupled to internal node N1, a body terminal coupled to receive a body bias voltage labeled “N ADJUST”, and a source coupled to a power supply voltage terminal labeled “VSS”. In the illustrated embodiment, VDD is coupled to receive a positive power supply voltage and VSS is coupled to ground. In other embodiments, the power supply voltages may be different depending on the integrated circuit technology. Inverter 26 has an input terminal coupled to internal node N1, and an output terminal for providing an output signal labeled “OUT”. P-channel transistor 22 and N-channel transistor 24 provide hysteresis for Schmitt trigger 10. P-channel transistor 22 has a source coupled to VDD, a gate coupled to the output terminal of inverter 26, a body terminal coupled to receive body bias voltage P ADJUST, and a drain coupled to the source of P-channel transistor 16. N-channel transistor 24 has a drain coupled to the source of N-channel transistor 18, a gate coupled to the output terminal of inverter 26, a body terminal coupled to receive body bias voltage N ADJUST, and a source coupled to power supply voltage terminal VSS. Body bias generator 28 has a plurality of input terminals for receiving a plurality of select signals labeled “P SELECT”, and an output terminal for providing body bias voltage P ADJUST. Body bias generator 30 has a plurality of input terminals for receiving a plurality of select signals labeled “N SELECT”, and an output terminal for providing body bias voltage N ADJUST. Note that in the illustrated embodiment, the body terminals of P-channel transistors 14 and 22 each receive the same body bias voltage P ADJUST, and the body terminals of N-channel transistors 20 and 24 each receive the same body bias voltage N ADJUST. In other embodiments, each of the transistors 14, 20, 22, and 24 may receive a different variable body bias voltage. Also, FIG. 1 illustrates body bias generators 28 and 30 as being two separate bias voltage generators. In other embodiments, body bias generators 28 and 30 may be implemented as one body bias generator having multiple outputs.

In one embodiment, input signal IN is a CMOS (complementary metal oxide semiconductor) logic signal. When input signal IN is a logic low, P-channel transistor 16 is conductive and N-channel transistor 18 is substantially non-conductive. The voltage at node N1 is a logic high, causing P-channel transistor 14 to be non-conductive and N-channel transistor 20 to be conductive. The logic high at node N1 causes inverter 26 to provide a logic low output signal OUT, causing P-channel transistor 22 to be conductive and N-channel transistor 24 to be substantially non-conductive. Therefore, internal node N1 is held at a logic high voltage via P-channel transistors 16 and 22.

When input signal IN transitions from a logic low to a logic high, the conductive P-channel transistor 16 starts to become non-conductive while N-channel transistor 18 starts to become conductive, thus causing the voltage at node N1 to begin transitioning from a logic high to a logic low. P-channel transistor 14 starts to become conductive when the threshold voltage of transistor 14 is reached and N-channel transistor 20 starts to become non-conductive. Note that P-channel transistor 14 starts to become conductive while P-channel transistor 22 is already conductive, momentarily making it more difficult for N-channel transistor 18, which is just starting to become conductive, to reduce the voltage at node N1. As the voltage at internal node N1 begins to be reduced, the output of inverter 26 (signal OUT) transitions to a logic high. The logic high signal OUT causes N-channel transistor 24 to become conductive and causes P-channel transistor 22 to be substantially non-conductive.

When input signal IN is a logic high, N-channel transistor 18 is conductive and P-channel transistor 16 is substantially non-conductive. The voltage at node N1 is a logic low, causing N-channel 20 to be substantially non-conductive and P-channel transistor 14 to be conductive. The logic low at node N1 causes inverter 26 to provide a logic high output signal OUT, thus causing N-channel transistor 24 to be conductive and causing N-channel transistor 22 to be substantially non-conductive. Therefore, internal node N1 is held low via N-channel transistors 18 and 24.

During a transition of the input signal IN from a logic high to a logic low, N-channel transistor 18 starts to become non-conductive while P-channel transistor becomes conductive. The voltage at internal node N1 will begin to increase when the threshold voltage of P-channel transistor 16 is reached and transistor 16 becomes sufficiently conductive to allow current flow through P-channel transistors 14 and 16. The output signal OUT will transition to a logic low. The logic low signal OUT will cause transistor 22 to become conductive and transistor 24 to become substantially non-conductive.

The threshold voltage (VT) of a MOS (metal oxide semiconductor) transistor is the voltage on which a drain current begins to flow through the channel of the transistor at an ON state. For bulk CMOS, one way to control the threshold voltage is by introducing impurities into a silicon substrate. For SOI (silicon-on-insulator) transistors the threshold voltage controllability is more difficult because the doping concentration which can be introduced for an SOI transistor is limited due to the relatively thin SOI layer. One way to change the threshold voltage of a bulk CMOS or SOI transistor is to change a bias voltage applied to the body terminal of the transistor. Changing the body bias, or back bias, voltage will change the voltage at which a drain current begins to flow.

In the embodiment of FIG. 1, the threshold voltages of transistors 14, 22, 20, and 24 are controlled in order to vary the hysteresis window of Schmitt trigger 1 0. The threshold voltage is changed by changing one or both of body bias voltages P ADJUST and N ADJUST provided to the body terminals of transistors 14, 20, 22, and 24. A magnitude of the body bias voltage is selectable using a control signal. In the embodiment of FIG. 1, multi-bit digital select signal P SELECT is used to select the voltage of body bias P ADJUST that is applied to the body terminals of P-channel transistors 14 and 22. Likewise, multi-bit digital select signal N SELECT is used to select the voltage of body bias N ADJUST that is applied to the body terminals of N-channel transistors 20 and 24. In another embodiment, each of transistors 14, 22, 20, and 24 may receive a different selectable body bias voltage using one or more different select signals, either analog or digital.

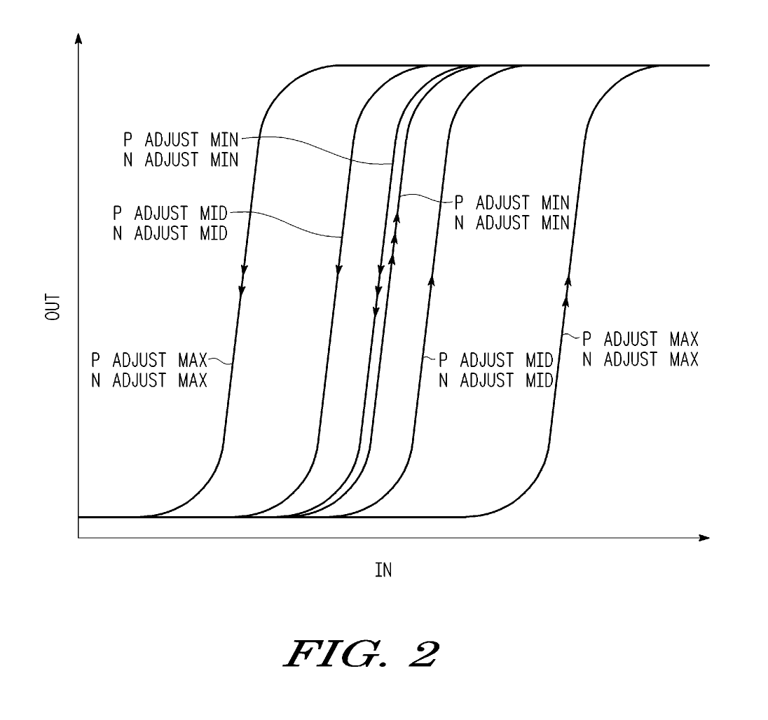

FIG. 2 illustrates the variable hysteresis window of Schmitt trigger 10 of FIG. 1. In FIG. 2, three example hysteresis windows are illustrated for minimum, mid, and maximum values for body bias voltages N ADJUST and P ADJUST. Generally, for an input signal IN transitioning from a logic low to a logic high, as discussed above, an increasing threshold voltage of transistors 22 and 24 increases the size of the hysteresis window by increasing the voltage required to make the transistors start to become conductive. Conversely, decreasing the threshold voltage of transistors 22 and 24 decreases the size of the hysteresis window by decreasing the voltage required to make transistors 22 and 24 start to become conductive. Given a power supply voltage of about one volt (V), the hysteresis window of Schmitt trigger 10 may be adjustable from about 10 millivolts (mV) to about 350 mV, where N ADJUST is selectable from about −1 V to 1 V and P ADJUST is selectable from about 0 V to 2 V. Specifically in FIG. 2, P ADJUST MAX is 2 V, P ADJUST MID is 1 V, and P ADJUST MIN is 0V. Also, N ADJUST MAX is −1 V, N ADJUST MID is 0V, and N ADJUST MIN is 1 V. As can be seen in FIG. 2, using minimum values for N ADJUST and P ADJUST results in a relatively narrow hysteresis window as shown by the hysteresis curves having three carrots (>>>). Changing N ADJUST and P ADJUST to relatively higher mid voltages, 0V and 1 V, respectively, results in a relatively wider hysteresis window illustrated in FIG. 2 with a single carrot (>). Changing N ADJUST and P ADJUST to a maximum values results in a still wider hysteresis window as shown by the curves having two carrots (>>).

Even though examples are illustrated in FIG. 2 for three different body bias voltages, any number of body bias voltages can be used in other embodiments.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed.

Some of the above embodiments, as applicable, may be implemented using a variety of different Schmitt trigger circuits. For example, although FIG. 1 and the discussion thereof describe an exemplary circuit, this exemplary circuit is presented merely to provide a useful reference in discussing various aspects of the invention. Of course, the description of the circuit has been simplified for purposes of discussion, and it is just one of many different types of appropriate circuits that may be used in accordance with the invention. Those skilled in the art will recognize that the boundaries between logic blocks are merely illustrative and that alternative embodiments may merge logic blocks or circuit elements or impose an alternate decomposition of functionality upon various logic blocks or circuit elements.

Thus, it is to be understood that the circuits depicted herein are merely exemplary, and that in fact many other circuits can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of circuits or intermedial components. Likewise, any two components so associated can also be viewed as being “operably connected,” or “operably coupled,” to each other to achieve the desired functionality.

Also for example, in one embodiment, the illustrated elements of circuit 10 are circuitry located on a single integrated circuit or within a same device. Alternatively, circuit 10 may include any number of separate integrated circuits or separate devices interconnected with each other. Furthermore, those skilled in the art will recognize that boundaries between the functionality of the above described operations merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A Schmitt trigger, comprising:
a first inverter having an input and an output;
a second inverter having an input coupled to the output of the first inverter and an output;
bias means for providing a first bias voltage on a first output terminal, wherein a magnitude of the bias voltage is selectable by a first input signal; and
a first transistor having a first current electrode coupled to a first power supply terminal, a control electrode coupled to the output of the second inverter, a second current electrode coupled to the output of the first inverter, and a body coupled to the first output terminal.

2. The Schmitt trigger of claim 1, wherein:
the first transistor has a first conductivity type;
the bias means is further characterized by being for providing a second bias voltage on a second output terminal; and
a magnitude of the second bias voltage is selectable by a second input signal;
further comprising a second transistor having a first current electrode coupled to a second power supply terminal, a control electrode coupled to the output of the second inverter, a second current electrode coupled to the output of the first inverter, and a body coupled to the second output terminal.

3. The Schmitt trigger of claim 2, wherein:
the first conductivity type is P type;
the second conductivity type is N type;
the first power supply terminal is a VDD terminal; and
the second power supply terminal is a ground terminal.

4. The Schmitt trigger of claim 1, wherein:
the first inverter comprises a second transistor having a first current electrode coupled to the output of the first inverter, a control electrode coupled to the input of the first inverter, and a second current electrode;
further comprising a third transistor having a first current electrode coupled to the second current electrode of the second transistor, a second current electrode coupled to the first power supply terminal, and a control electrode coupled to the output of the first inverter;
wherein the second current electrode of the first transistor is coupled to the output of the first inverter through the second transistor.

5. The Schmitt trigger of claim 4, wherein the third transistor has a body coupled to the first output terminal.

6. The Schmitt trigger of claim 4, wherein:
the first inverter comprises a fourth transistor having a first current electrode coupled to the output of the first inverter, a control electrode coupled to the input of the first inverter, and a second current electrode;
further comprising a fifth transistor having a first current electrode coupled to the second current electrode of the fourth transistor, a second current electrode coupled to a second power supply terminal, and a control electrode coupled to the output of the first inverter.

7. The Schmitt trigger of claim 6, wherein:
the bias means is further characterized by being for providing a second bias voltage on a second output terminal; and
a magnitude of the bias voltage is selectable by a second input signal;
further comprising a sixth transistor having a first current electrode coupled to a second power supply terminal, a control electrode coupled to the output of the second inverter through the fourth transistor, a second current electrode coupled to the output of the first inverter, and a body coupled to the second output terminal.

8. The Schmitt trigger of claim 7, wherein:
the first transistor is P type;
the second transistor is P type;
the third transistor is P type;
the fourth transistor is N type;
the fifth transistor is N type; and
the sixth transistor is N type.

9. The Schmitt trigger of claim 1, wherein the first input signal comprises a plurality of bits.

10. The Schmitt trigger of claim 1, wherein hysteresis of the Schmitt trigger increases with an increase in magnitude of the first bias voltage.

11. In a Schmitt trigger, a method comprising:
providing a first inverter having an input for receiving an input signal and having an output;
providing a first transistor between a first power supply terminal and the output of the first inverter;
selecting a threshold voltage for the first transistor;
applying the input signal at a first logic state to the input of the first inverter, wherein the first transistor becomes conductive at a first voltage;
transitioning the input signal from the first logic state to a second logic state, wherein the first transistor becomes non-conductive at a second voltage different from the first voltage.

12. The method of claim 11, wherein the step of selecting is further characterized by a first select signal selecting the threshold voltage of the first transistor.

13. The method of claim 11, further comprising;
changing the threshold voltage of the first transistor; and
transitioning the input signal from the first logic state to a second logic state, wherein the first transistor becomes non-conductive at a third voltage different from the first voltage and the second voltage.

14. The method of claim 11, further comprising:
providing a second transistor between a second power supply terminal and the output of the first inverter; and
selecting a threshold voltage for the second transistor;
wherein the step of applying the input signal at a first logic state to the input of the first inverter causes the second transistor to become non-conductive;

15. The method of claim 14, further comprising:
changing the threshold voltage of the second transistor; and
transitioning the input signal from the second logic state to the first logic state to cause the first transistor to become conductive at a third voltage different from the first voltage and the second voltage;

16. The method of claim 11, further comprising changing hysteresis of the Schmitt trigger by changing the threshold voltage of the first transistor.

17. A Schmitt trigger, comprising:
a first inverter having an input for receiving an input signal and having an output;
first current means for supplying a first current to the output during a first portion of a transition of the input signal from a first logic state to a second logic state; and
select means for altering a magnitude of the first current that is supplied to the first output during the first portion of the transition of the input signal from the first logic state to the second logic state.

18. The Schmitt trigger of claim 17, wherein the first current means comprises a first transistor having a threshold voltage that is selectable by the select means:

19. The Schmitt trigger of claim 17, wherein the first current means comprises:
bias means for providing a first bias voltage on a first output terminal, wherein a magnitude of the bias voltage is selectable by a first input signal; and
a first transistor having a first current electrode coupled to a first power supply terminal, a control electrode coupled to the output of the second inverter, a second current electrode coupled to the output of the first inverter, and a body coupled to the first output terminal.

20. The Schmitt trigger of claim 19, wherein:
the bias means provides a bias voltage to a body of the first transistor, and a magnitude of the bias voltage is selectable by a multiple bit select signal.
